(19) United States
(12) Patent Application Publication
(10) Pub. No.: US 2022/0251725 A1
(43) Pub. Date: Aug. 11, 2022

(54) METHOD OF GROWING ON-AXIS SILICON CARBIDE SINGLE CRYSTAL BY REGULATING SILICON CARBIDE SOURCE MATERIAL IN SIZE

(71) Applicant: NATIONAL CHUNG SHAN INSTITUTE OF SCIENCE AND TECHNOLOGY, Taoyuan City (TW)

(72) Inventors: CHIH-WEI KUO, Hsinchu City (TW); CHENG-JUNG KO, New Taipei City (TW); HSUEH-I CHEN, Taoyuan City (TW); JUN-BIN HUANG, Taoyuan City (TW); YING-TSUNG CHAO, Taoyuan City (TW); CHIA-HUNG TAI, New Taipei City (TW)

(21) Appl. No.: 17/170,896

(22) Filed: Feb. 9, 2021

(51) Int. Cl. C30B 23/02; C30B 29/36; C23C 14/06; C23C 14/24

(52) U.S. Cl. CPC C30B 23/02; C23C 14/243; C23C 14/0635; C30B 29/36

(57) ABSTRACT

A method of growing on-axis silicon carbide single crystal includes the steps of (A) sieving a silicon carbide source material by size, and only the part that has a size larger than 1 cm is adopted for use as a sieved silicon carbide source material; (B) filling the sieved silicon carbide source material in the bottom of a graphite crucible; (C) positioning an on-axis silicon carbide on a top of the graphite crucible to serve as a seed crystal; (D) placing the graphite crucible having the sieved silicon carbide source material and the seed crystal received therein in an induction furnace for the physical vapor transport process; (E) starting a silicon carbide crystal growth process; and (F) obtaining a silicon carbide single crystal.

### BACKGROUND OF THE INVENTION

### 1. Field of the Invention

The present disclosure relates to a method of growing on-axis silicon carbide (SiC) single crystal, and in particular to a method of growing on-axis silicon carbide single crystal, in which an adopted silicon carbide source material is regulated and controlled in size.

### 2. Description of the Related Art

Following the development in the technological field, high power density and miniaturized high-frequency devices have become an indispensable requirement in many related industrial fields. However, it seems that the development of silicon has reached at a high limit, rendering device performance enhancement to be limited by the material itself. It is therefore necessary to break the bottleneck by positively developing a new material to replace the materials used by the existing industries. Among a variety of ceramic materials, silicon carbide wafer places a very important role because silicon carbide substrate has excellent properties that could not be provided by the conventional silicon substrate and high frequency has also gradually become one of the important targets. With the excellent conditions thereof, silicon carbide can solve the problem of the conventional silicon material that fails to provide desired specifications. For instance, silicon carbide has an energy gap value three times higher than that of the conventional silicon substrate, a breakdown field ten times higher than that of the conventional silicon substrate, and a saturated electron drift velocity two times higher than that of the conventional silicon substrate. The silicon carbide is usually grown on an off-axis seed crystal to form surface growth steps, which in turn enables crystal quality control to lower defect density. Recently, the 5G communication market emerges quickly, and the substrates for the high-frequency devices are mainly on-axis substrates. In the past, on-axis crystal is obtained mainly through processing of an off-axis crystal. However, the above way would reduce the crystal utilization rate to largely increase the cost of producing the on-axis substrate.

Presently, silicon carbide crystal is generally prepared using an off-axis seed crystal mainly for two reasons, namely, reducing defect density and maintaining desired crystal form.

Regarding the reduction of defect density, the preparation of large-size and low defect density silicon carbide crystal has always been a focused point being researched. According to past research experiences, defects tend to extend when the seed crystal grows in the direction of c-axis. The defects include micropipes (MPs), threading dislocations (TDs), stacking faults (SFs) and large-angle grain boundary (LAGBs). To reduce the defects of silicon carbide crystal, most of the conventional methods of preparing silicon carbine crystal use an off-axis seed crystal. Meanwhile, to reduce the cost, 8-degree off-axis seed crystal used in the early stage has been changed to 4-degree off-axis seed crystal gradually. However, while the use of off-axis seed crystal is advantageous to the growth of silicon carbide crystal, the utilization rate of the off-axis silicon carbide crystal would largely reduce when they are applied to the on-axis substrate in the subsequent application. CREE, Inc. of USA has been devoted in the research of silicon carbide crystal growth for a long time. It discloses a seed holder that enables a seed crystal growth surface to form an angle of 0°<a≤20° relative to a horizontal plane. However, since there is a significant difference in the thermal field in an axial direction when growing silicon carbide crystal by the technique of physical vapor transport (PVT), the holding of the seed crystal at an off-axis angle will cause more inconsistency in the temperature field around the crystal, rendering the crystal growth process uneasy to control.

The purpose of maintaining crystal form is to stabilize the crystal form grown through a surface step model. As shown in FIG. 1, when atoms are adsorbed to the crystal surfaces, according to the principle of energy balance, the atoms would immigrate to the steps or kink to stabilize their energy and would bond together at the steps when the distance is not a problem. This surface step growth model is referred to as Kossel model or lateral growth.

In conclusion, since the currently used silicon carbide crystal growth source material usually has a crystal grain size ranged from 300 to 800 μm, this relatively small crystal grain size gives the source material a relatively large specific surface area at the early crystal growth stage, which leads to uncontrollable production of a large amount of C/Si vapor and an uncontrollable deposition model on the on-axis seed crystal. As a result, the crystal form could not be controlled and a polycrystal is formed. It is therefore tried by the inventor to develop a method of growing on-axis silicon carbide single crystal, which effectively reduces the uncontrollable production of C/Si vapor at the early crystal growth stage, making the growth surface has reaction conditions advantageous to the growth of desired target crystal form to finally obtain the desired silicon carbide single crystal.

### BRIEF SUMMARY OF THE INVENTION

An objective of the present disclosure is to provide a method of growing on-axis silicon carbide single crystal by the technique of physical vapor transport (PVT. In the method of the present disclosure, the size of a silicon carbide source material is regulated and controlled according to a selected on-axis seed crystal, and the vapor concentration and the evaporation rate of a gas source set for the silicon carbide source material are also under control, so as to effectively reduce the defect density of the grown crystal and to maintain the desired crystal form. In this manner, it is able to break the limit of having to use an off-axis silicon carbide as the seed crystal for growing a silicon carbide crystal and to reduce the cost for preparing an on-axis substrate.

To achieve at least the above objective, an embodiment of the method of growing on-axis silicon carbide single crystal according to the present disclosure includes the steps of (A) sieving a silicon carbide source material by size, and only the part that has a size larger than 1 cm is adopted for use as a sieved silicon carbide source material; (B) filling the sieved silicon carbide source material in the bottom of a graphite crucible; (C) positioning an on-axis silicon carbide on a top of the graphite crucible to serve as a seed crystal; (D) placing the graphite crucible having the sieved silicon carbide source material and the seed crystal received therein in an induction furnace for the physical vapor transport process; (E) starting a silicon carbide crystal growth process; and (F) obtaining a silicon carbide single crystal.

Preferably, the sieved silicon carbide source material can be any one of a flat polygon having three sides or more, a ball, a ring, a prism and a cone in shape.

Preferably, the sieved silicon carbide source material has any dimension larger than 1 cm.

Preferably, the sieved silicon carbide source material has a density equal to or larger than 3 g/cm³.

Preferably, the sieved silicon carbide source material has purity equal to or larger than 99.99%.

Preferably, the sieved silicon carbide source material has a nitrogen concentration equal to or lower than 1E16 cm⁻³.

Preferably, the sieved silicon carbide source material has a boron concentration equal to or lower than 1E16 cm⁻³.

Preferably, the sieved silicon carbide source material has a phosphors concentration equal to or lower than 1E16 cm⁻³.

Preferably, the sieved silicon carbide source material has an aluminum concentration equal to or lower than 1E16 cm⁻³.

Preferably, the sieved silicon carbide source material has any dimension ranged between 1.5 to 2 centimeters.

The above brief summary of the invention and the following detailed description of the invention and the accompanying drawings are provided to facilitate understanding of the manner and technical means adopted by the present disclosure to achieve the desired objects and effects. Other objects and advantages of the present disclosure will be described in detail in the following description and the accompanying drawings.

### BRIEF DESCRIPTION OF THE DRAWINGS

FIG. 1 is a conceptual view showing the mechanism of crystal lateral growth.

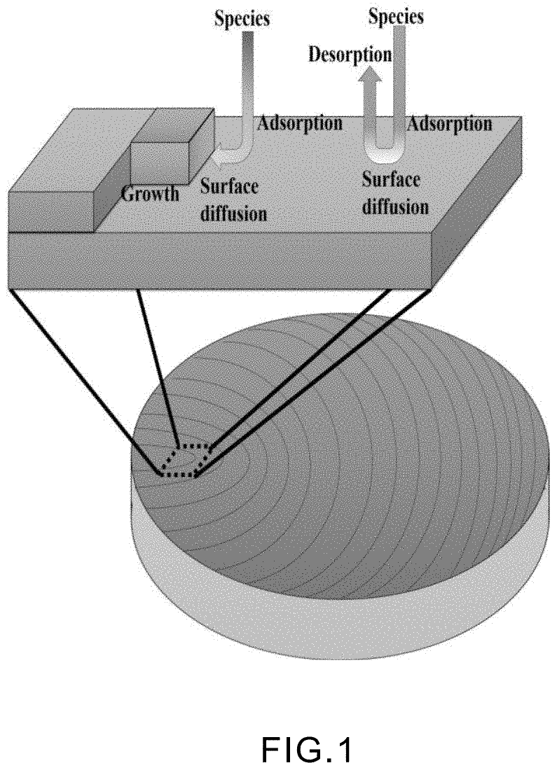

FIG. 2 is a conceptual view showing a mechanism of forming a two-dimensional nuclide according to the present disclosure.

FIG. 3 is a conceptual view showing a graphite crucible for SiC crystal growth according to the present disclosure.

FIG. 4 is a picture showing a 4H-SiC single crystal produced according to the present disclosure.

FIG. 5 is a flowchart showing the steps included in the method of growing on-axis SiC single crystal according to the present disclosure.

### DETAILED DESCRIPTION OF THE INVENTION

To facilitate understanding of the objects, characteristics and effects of this present disclosure, an embodiment together with the attached drawings for the detailed description of the present disclosure are provided. It is noted the present disclosure can be implemented or applied in other embodiments, and many changes and modifications in the described embodiment can be carried out without departing from the spirit of the disclosure, and it is also understood that the preferred embodiment is only illustrative and not intended to limit the present disclosure in any way.

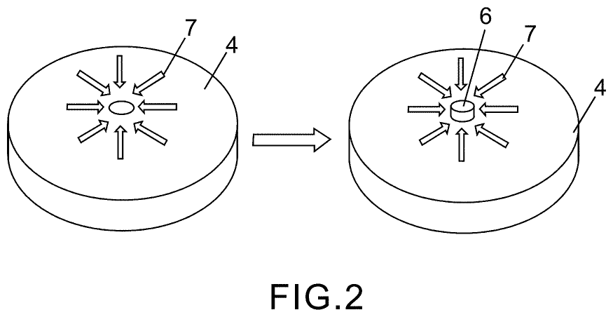

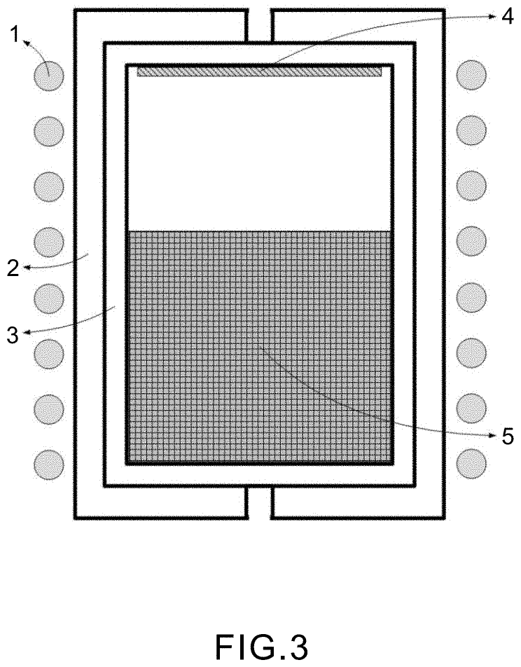

Please refer to FIG. 2, which is a conceptual view showing a mechanism of forming a two-dimensional nuclide according to the present disclosure, and to FIG. 3, which is a conceptual view showing a graphite crucible for silicon carbide (SiC) crystal growth according to the present disclosure. The present disclosure provides a method of growing on-axis silicon carbide single crystal. Generally, when preparing SiC single crystal by the technique of physical vapor transport (PVT), a SiC source material is caused to sublimate at a high temperature. As shown in FIG. 3, a crucible 3 containing a seed crystal 4 and an amount of sieved silicon carbide source material 5 is depressurized in an atmosphere of an inert gas and heated to a temperature about 2000 to 2400° C. The sieved silicon carbide source material 5 sublimates in the process of depressurizing and heating. Meanwhile, a gas source 7 is supplied under control to a surface of the seed crystal 4 for crystal growth. As to the seed crystal 4, it can be a 4-inch or a 6-inch on-axis silicon carbide single crystal.

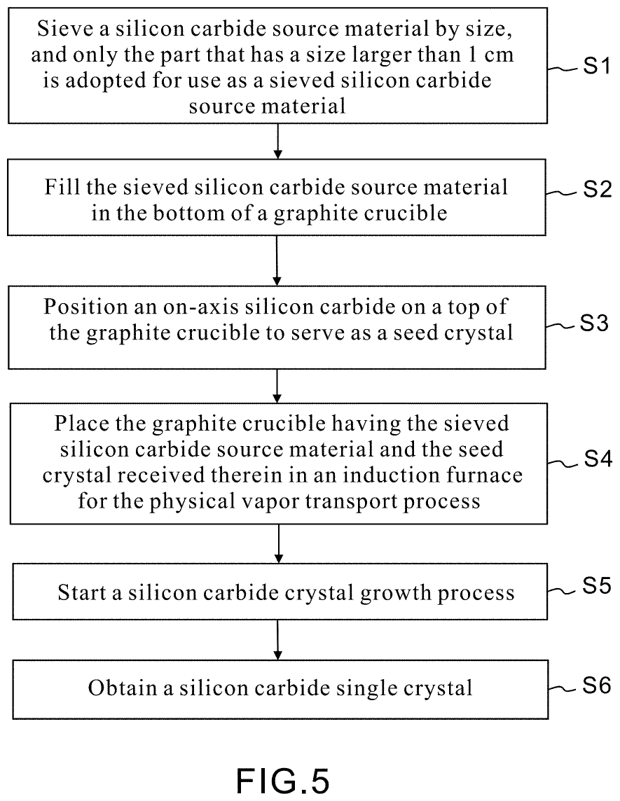

Please refer to FIG. 5, which is a flowchart showing steps S1 to S6 included in the method of growing on-axis SiC single crystal according to the present disclosure. More specifically, in the step S1, a silicon carbide source material is sieved by size, and only the part that has a size larger than 1 cm is adopted for use as a sieved silicon carbide source material 5. In the step S2, the sieved silicon carbide source material 5 is filled in the bottom of a graphite crucible 3. In the step S3, a piece of on-axis silicon carbide is positioned on a top of the graphite crucible 3 to serve as a seed crystal 4. In the step S4, the graphite crucible 3 having the sieved silicon carbide source material 5 and the seed crystal 4 received therein is placed in an induction furnace 1 for the physical vapor transport process. In the step S5, the silicon carbide crystal growth process is progressed. In the step S6, a silicon carbide single crystal is obtained.

In the illustrated embodiment of the present disclosure, the silicon carbide crystal growth is achieved by the technique of physical vapor transport. Generally, when using the physical vapor transport process in the silicon carbide crystal growth, a growth temperature of about 2000 to 2400° C. and a crystal growth pressure of 0.1 to 50 torr are required, and a growth rate generally ranged between 100 and 200 μm/hr can be achieved. Further, expensive manufacturing material and long growth time are needed. Thus, it is very important to increase the good yield and reduce the cost of the growth of silicon carbide single crystal, which may be achieved by lowering the defect density of the silicon carbide crystal prepared from on-axis seed crystal and upgrading the usability of the grown crystal. In the method of the present disclosure, through the regulating and controlling of the size of the silicon carbide source material and the controlling of the concentration and evaporation rate of the silicon carbide source material, the crystal growth surface can have reaction conditions advantageous to the growth of desired target crystal form to finally obtain the silicon carbide single crystal.

As having been mentioned in the background of the invention, the currently used silicon carbide crystal growth source material usually has a crystal grain size ranged from 300 to 800 μm. Since this crystal grain size is relatively small, the source material has a relatively large specific surface area at the early crystal growth stage, which leads to uncontrollable production of a large amount of C/Si vapor and an uncontrollable deposition model on the on-axis seed crystal. As a result, the crystal form could not be controlled and a polycrystal is formed. Therefore, in the method of the present disclosure, the silicon carbide source material is subjected to a size regulation and control, in which the silicon carbide material is sieved by size and only the part having any dimension larger than 1 cm is adopted for use as a sieved source material 5. Preferably, the sieved silicon carbide source material 5 has any dimension ranged between 1.5 to 2 centimeters so that the problem of uncontrollable C/Si vapor production in the early stage of crystal growth can be effectively reduced. Further, in the method of the present disclosure, appropriate growth temperature and thermal field distribution are well controlled so that a center of the seed crystal 4 is nucleated to form a two-dimensional nuclide 6 in the early stage of silicon carbide crystal growth, as shown in FIG. 2. The two-dimensional nuclide 6 will form a specific crystal form of 4H or 6H according to different growth temperatures. Once the crystal form is determined, atoms will start stacking according to the nuclide to thereby obtain the silicon carbide single crystal.

In the illustrated embodiment, the sieved silicon carbide source material 5 has any dimension larger than 1 cm and can be irregular in shape, including but not limited to a flat polygon having three sides or more, a ball, a ring, a prism and a cone; and has a purity equal to or larger than 99.99%. Further, in view of the expensive manufacturing material and the long crystal growth time for the silicon carbide crystal growth, the sieved silicon carbide source material used in the method of the present disclosure has a density equal to or larger than 3 g/cm³. Therefore, a relatively large silicon carbide single crystal can be obtained at the same growth time.

In the illustrated embodiment of the present disclosure, the sieved silicon carbide source material selected for crystal growth has a nitrogen concentration equal to or lower than 1E16 cm⁻³, a boron concentration equal to or lower than 1E16 cm⁻³, a phosphors concentration equal to or lower than 1E16 cm⁻³, and an aluminum concentration equal to or lower than 1E16 cm⁻³. These four elements are commonly seen elements that have an influence on the electrical property of the silicon carbide. Following the increased using amount of high-frequency devices, the demand for semi-insulating silicon carbide wafer also increases quickly. Therefore, the purpose of lowering different element concentrations is to avoid the forming of an electrically conductive silicon carbide crystal owing to doping. Lastly, by regulating and controlling the concentration of the sieved silicon carbide source material 5 and providing appropriate crystal growth temperature and thermal field distribution, it is able for the seed crystal 4 to nucleate at the center thereof instead of its outer edge.

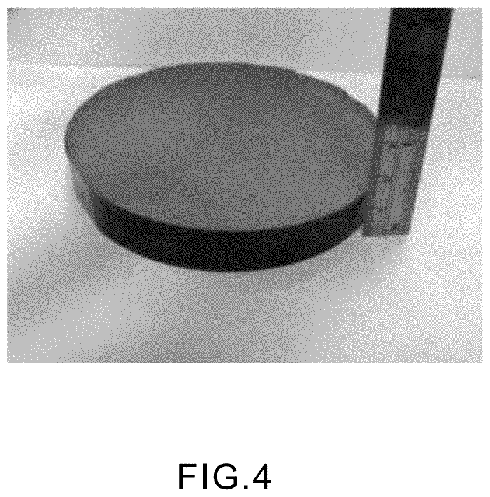

Please refer to FIG. 3. In the illustrated embodiment of the present disclosure, the sieved silicon carbide source material 5 having a size larger than 1 cm is selected for use, which is cleaned using de-ionized water and is then dried for filling in the bottom of the graphite crucible 3, in which silicon carbide crystal grows. An on-axis silicon carbide wafer for using as a seed crystal 4 is fixed to a top of the graphite crucible 3, and then, the graphite crucible 3 is mounted in a thermal insulation material 2 to complete the assembling of the graphite crucible 3 for silicon carbide single crystal growth. The graphite crucible 3 is then positioned in the induction furnace 1 for the silicon carbide crystal growth process to progress at a growth temperature ranged between 2000 and 2200° C. under a pressure of 0.1 to 10 torr for 50 to 100 hours, so as to obtain a silicon carbide single crystal having a thickness of 7.5 to 20 mm, as shown in FIG. 4.

In conclusion, the present disclosure is a control method that uses an on-axis silicon carbide as a seed crystal 4 to grow a silicon carbide single crystal. By regulating and controlling the size of the silicon carbide source material 5 and by controlling the evaporation rate and the growth surface concentration of the gas source 7 supplied to the sieved silicon carbide source material 5, reaction conditions advantageous to the growth of a specific silicon carbide crystal form can be achieved for producing a uniform silicon carbide single crystal. With the present disclosure, it is able to overcome the problems in the conventional method of silicon carbide growth, including the use of an off-axis seed crystal, the lowered crystal utilization and the high production cost. The method of the present disclosure has the advantages of reducing the cost of crystal growth and using an on-axis seed crystal to save the procedures of changing an off-axis crystal orientation into an on-axis crystal orientation. Through saving of the crystal processing procedures, it is able to upgrade the crystal utilization rate while simplifying the complicated processing steps at the same time.

Further, in the conventional silicon carbide single crystal growth method, the main way of solving the demand for on-axis wafer is to change the off-axis crystal orientation into an on-axis crystal orientation and then dice the wafer. This would result in a large quantity of residual loss and complicated orientation processing procedures. In the method of the present disclosure, the using of an on-axis seed crystal 4 can effectively upgrade the utilization rate of the prepared silicon carbide single crystal and reduce the additional orientation changing procedures; and wafer dicing, grinding and polishing can be directly performed on the prepared silicon carbide crystal to largely reduce the loss of off-axis crystal and the complexity of the wafer dicing process and accordingly, achieve the effect of reduced silicon carbide processing cost.

While the present disclosure has been described by means of a specific embodiment, numerous modifications and variations could be made thereto by those skilled in the art without departing from the scope and spirit of the present disclosure set forth in the claims.

1. A method of growing on-axis silicon carbide single crystal, comprising the following steps:
(A) sieving a silicon carbide source material by size, and only the part that has a size larger than 1 cm is adopted for use as a sieved silicon carbide source material;
(B) filling the sieved silicon carbide source material in the bottom of a graphite crucible;
(C) positioning an on-axis silicon carbide on a top of the graphite crucible to serve as a seed crystal;
(D) placing the graphite crucible having the sieved silicon carbide source material and the seed crystal received therein in an induction furnace for the physical vapor transport process;
(E) starting a silicon carbide crystal growth process; and
(F) obtaining a silicon carbide single crystal.

2. The method of growing on-axis silicon carbide single crystal according to claim 1, wherein the sieved silicon carbide source material can be any one of a flat polygon having three sides or more, a ball, a ring, a prism and a cone in shape.

3. The method of growing on-axis silicon carbide single crystal according to claim 1, wherein the sieved silicon carbide source material has any dimension larger than 1 cm.

4. The method of growing on-axis silicon carbide single crystal according to claim 1, wherein the sieved silicon carbide source material has a density equal to or larger than 3 g/cm³.

5. The method of growing on-axis silicon carbide single crystal according to claim 1, wherein the sieved silicon carbide source material has purity equal to or larger than 99.99%.

6. The method of growing on-axis silicon carbide single crystal according to claim 1, wherein the sieved silicon carbide source material has a nitrogen concentration equal to or lower than 1E16 cm⁻³.

7. The method of growing on-axis silicon carbide single crystal according to claim 1, wherein the sieved silicon carbide source material has a boron concentration equal to or lower than 1E16 cm⁻³.

8. The method of growing on-axis silicon carbide single crystal according to claim 1, wherein the sieved silicon carbide source material has a phosphors phosphorous concentration equal to or lower than 1E16 cm⁻³.

9. The method of growing on-axis silicon carbide single crystal according to claim 1, wherein the sieved silicon carbide source material has an aluminum concentration equal to or lower than 1E16 cm⁻³.

10. The method of growing on-axis silicon carbide single crystal according to claim 1, wherein the sieved silicon carbide source material has any dimension ranged between 1.5 to 2 centimeters.
